(19) United States
(12) Patent Application Publication
(10) Pub. No.: US 2025/0151301 A1
(43) Pub. Date: May 8, 2025

(54) SEMICONDUCTOR DEVICE AND POWER CONVERSION DEVICE

(71) Applicant: Minebea Power Semiconductor Device Inc., Hitachi-shi, Ibaraki (JP)

(72) Inventor: Masaki SHIRAISHI, Hitachi-shi, Ibaraki (JP)

(21) Appl. No.: 18/867,035

(22) PCT Filed: Apr. 4, 2023
(86) PCT No.: PCT/JP2023/013889

§ 371 Date: Nov. 19, 2024

(30) Foreign Application Priority Data
May 23, 2022 (JP) 2022-083954

(51) Int. Cl. H10D 12/00; H10D 62/10; H10D 64/27

(52) U.S. Cl. CPC H10D 12/481; H10D 64/518; H10D 62/103

(57) ABSTRACT

The purpose of the present invention is, in an RC-IGBT, to provide a semiconductor device that can suppress a snapback phenomenon when the IGBT is on, and hole injection from the IGBT region to a diode region when the diode is conductive, using a simple structure. The semiconductor device having an IGBT region 21 and a diode region 22 within the same chip is characterized in that the gate resistance R of the IGBT near the boundary of the IGBT region 21 and the diode region 22 is greater than the gate resistance of the IGBT near the center of the IGBT region 21.

### TECHNICAL FIELD

The present invention relates to a semiconductor device and a power conversion device.

### BACKGROUND ART

In a reverse-conducting insulated gate bipolar transistor (RC-IGBT) obtained by incorporating an insulated gate bipolar transistor (IGBT) and a diode within the same chip, a termination region can be shared between the IGBT and the diode, and thus it is possible to reduce a chip size. In addition, since the IGBT and the diode operate at different timings, heat due to a loss generated in one of an IGBT region or a diode region is dispersed to the other thereof, allowing the heat to be discharged throughout the chip, and thus it is also possible to reduce a thermal resistance.

On the other hand, in the RC-IGBT, when the IGBT is turned on, electrons implanted from the front surface side of the IGBT, particularly in the vicinity of a boundary portion with the diode, do not escape from a p layer, which is a collector layer on the back surface side of the IGBT, but escape to an n+ layer, which is a cathode layer of the diode, and thus there is a problem in that hole implantation from the p layer on the back surface does not occur unless a voltage greater than or equal to a built-in voltage of a pn junction on the back surface side is applied, that is, a snapback phenomenon occurs when the IGBT is turned on.

In addition, in the RC-IGBT, when the IGBT is turned off, the potential of a front surface electrode becomes higher than the potential of a back surface electrode, and the diode is conductive, the hole implantation from the p layer, which is a body layer on the front surface side of the IGBT, particularly in the vicinity of the boundary portion with the diode into the diode region also occurs, and the concentration of the holes in a drift layer increases in the vicinity of the boundary portion between the diode region and the IGBT region. Thereafter, when the potential of the front surface electrode becomes lower than the potential of the back surface electrode and the diode performs a recovery operation, the holes in the drift layer flow toward the front surface electrode, causing a recovery current to flow. However, since the concentration of the holes is high in the vicinity of the boundary portion between the diode region and the IGBT region, there is a problem in that the recovery current flows at a high density in the vicinity of the boundary portion and a high load is applied to a semiconductor substrate, that is, hole implantation from the IGBT region into the diode region occurs when the diode is conductive.

Here, Patent Literature 1 describes a semiconductor device in which a semiconductor substrate includes an IGBT region that overlaps a collector region, a diode region that overlaps a cathode region, a drift region that is distributed across from the IGBT region to the diode region, a body region, a body contact region, and an emitter region that are disposed in the IGBT region, and an anode region and an anode contact region that are disposed in the diode region, wherein the body region includes a first body region and a second body region having a lower p-type impurity concentration than the first body region and the anode region, the second body region is adjacent to the anode region, and the first body region is adjacent to the second body region on a side opposite to the anode region (Abstract, FIG. 2).

According to the semiconductor device of Patent Literature 1, since the p-type impurity concentration in the second body region adjacent to the anode region is low, when the diode is turned on, few holes flow from the second body region toward the cathode region, and the hole concentration does not become so high in the drift region in the vicinity of the boundary between the diode region and the IGBT region. This prevents a high recovery current flowing in the vicinity of the boundary between the diode region and the IGBT region during a recovery operation, thereby reducing the load on the semiconductor substrate (paragraph 0007).

In this way, Patent Literature 1 describes a structure for solving the problem of the hole implantation from the IGBT region into the diode region occurring when the diode is conductive. In addition, although Patent Literature 1 does not mention the problem of the snapback phenomenon occurring when the IGBT is turned on, it is considered that this problem can be solved by the structure of Patent Literature 1.

### CITATION LIST

### Patent Literature

Patent Literature 1: Japanese Patent Application Publication No. 2019-106430

### SUMMARY OF INVENTION

### Technical Problem

However, in Patent Literature 1, in order to make the p-type impurity concentration in the body region of the IGBT in the vicinity of the boundary portion (the second body region of the IGBT adjacent to the anode region) lower than that in the body region of the IGBT in the vicinity of the central portion (the first body region of the IGBT), a new photolithography process or a new implantation process is required, which poses a problem of increased manufacturing costs.

Therefore, an object of the invention is to provide a semiconductor device as an RC-IGBT by which a snapback phenomenon occurring when an IGBT is turned on and hole implantation from an IGBT region into a diode region occurring when a diode is conductive can be suppressed with a simple structure and a power conversion device.

### Solution to Problem

In order to achieve this object, a semiconductor device of the present invention is, for example, a semiconductor device having an IGBT region and a diode region in the same chip, wherein a gate resistance of an IGBT in the vicinity of a boundary portion between the IGBT region and the diode region is greater than a gate resistance of an IGBT in the vicinity of a central portion of the IGBT region.

In addition, a power conversion device of the present invention includes, for example, the semiconductor device described above as a switching element.

### Advantageous Effects of Invention

According to the present invention, due to a simple structure in which the gate resistance of the IGBT in the vicinity of the boundary portion is made larger than that in the vicinity of the central portion, when the IGBT is turned on, the IGBT in the vicinity of the central portion, which is away from the vicinity of the boundary portion, is turned on before the IGBT in the vicinity of the boundary portion. As a result, a path through which the electrons from the IGBT in the vicinity of the central portion flow near the front surface of the pn junction portion on the back surface side to reach the cathode layer of the diode becomes longer, and thus a voltage drop occurs while the electrons flow over that length, resulting in a forward bias, and when the voltage exceeds the built-in voltage, the hole implantation from the collector layer on the back surface side starts, and thus the snapback phenomenon occurring when the IGBT is turned on can be suppressed.

In addition, due to a simple structure in which the gate resistance of the IGBT in the vicinity of the boundary portion is made larger than that in the vicinity of the central portion, when the IGBT is turned off, the IGBT in the vicinity of the central portion, which is away from the vicinity of the boundary portion, is turned off before the IGBT in the vicinity of the boundary portion is turned off.

The IGBT in the vicinity of the central portion which is turned off first is away from the vicinity of the boundary portion, and thus the amount of the hole implantation therefrom is small. In the IGBT in the vicinity of the boundary portion which is turned off later, a time for the hole implantation to occur is short, and thus the amount of the hole implantation therefrom can be reduced. As a result, the hole implantation from the IGBT region into the diode region occurring when the diode is conductive can be suppressed compared to the case in which the IGBTs are turned off at the same time.

### BRIEF DESCRIPTION OF DRAWINGS

FIG. 1 is a cross-sectional view illustrating a schematic configuration of a semiconductor device of Example 1.

FIG. 2 is a plan view illustrating a shape of a gate wiring of the semiconductor device of Example 1.

FIG. 3 is a plan view illustrating a shape of a gate wiring of a semiconductor device of Example 2.

FIG. 4 is a current-voltage characteristic illustrating a snapback phenomenon in an RC-IGBT.

### DESCRIPTION OF EMBODIMENTS

Hereinafter, examples of the present invention will be described with reference to the drawings. In each drawing and each example, the same or similar constituent elements are designated by the same reference signs, and the overlapping description will be omitted.

### Example 1

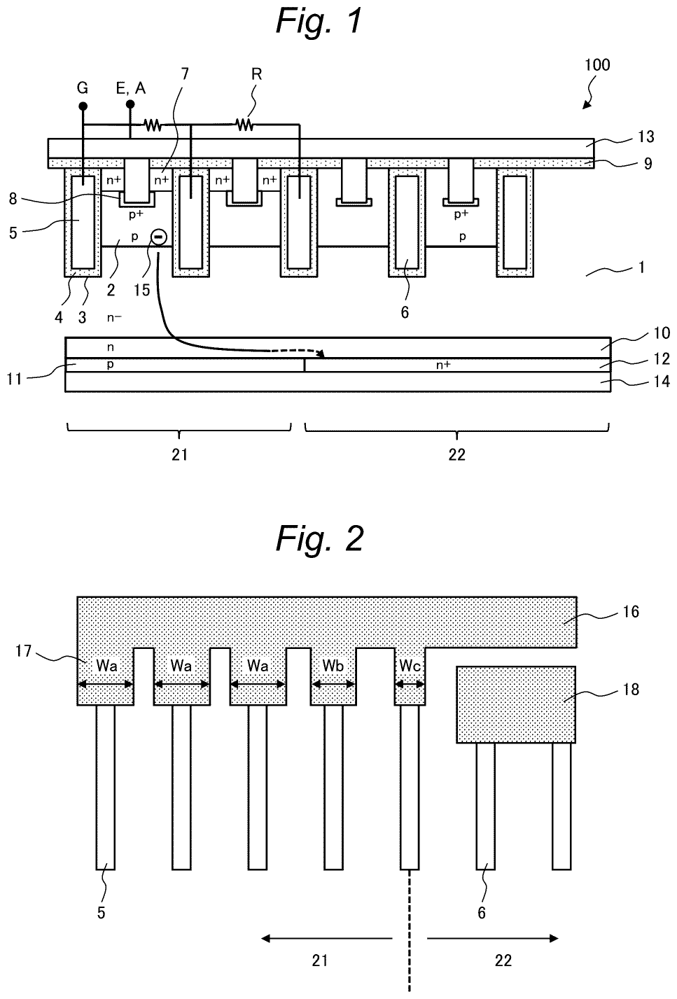

FIG. 1 is a cross-sectional view illustrating a schematic configuration of a semiconductor device of Example 1.

A semiconductor device 100 of Example 1 is an RC-IGBT and includes an IGBT region 21 and a diode region 22 in the same chip (on the same semiconductor substrate).

An IGBT is formed in the IGBT region 21, and the IGBT includes, for example, a drift layer 1 of a first conductivity type (an n-type in FIG. 1), a trench 3, a gate electrode 5 which is provided in the trench 3, a body layer 2 of a second conductivity type (a p-type in FIG. 1) which is provided adjacent to the trench 3 on a front surface side relative to the drift layer 1, an emitter layer 7 of a first conductivity type provided on a front surface side of the body layer 2, and a collector layer 11 of a second conductivity type provided on a back surface side relative to the drift layer 1.

In FIG. 1, description is made using an example in which the first conductivity type is the n-type and the second conductivity type is the p-type, but the present invention is not limited to this, and the first conductivity type may be the p-type and the second conductivity type may be the n-type. In this case, electrons and holes are reversed.

A diode is formed in the diode region 22, the diode includes, for example, the drift layer 1, the body layer 2 functioning as an anode layer of a second conductivity type provided on a front surface side relative to the drift layer 1, and a cathode layer 12 of a first conductivity type provided on a back surface side relative to the drift layer 1.

In addition, the semiconductor device 100 includes a buffer layer 10 of a first conductivity type which is formed between the collector layer 11 or the cathode layer 12 and the drift layer 1, a front surface electrode 13, an interlayer insulating film 9 which is provided between the emitter layer 7 or the body layer 2 and the front surface electrode 13, and a back surface electrode 14, which are common to the IGBT region 21 and the diode region 22.

The front surface electrode 13 is connected to the body layer 2 via a contact hole and a body contact layer 8 of a second conductivity type in the IGBT region 21 and the diode region 22. Therefore, potential of the front surface electrode 13 is at an emitter potential E and an anode potential A.

The gate electrode 5 is adjacent to the body layer 2 and the emitter layer 7 via an insulating film 4 formed in the trench 3. A gate potential G is supplied to the gate electrode 5 from a gate drive circuit (not shown) or the like.

The diode region 22 also includes a trench 3, and an insulating film 4 and a dummy electrode 6 are provided in the trench 3 of the diode region 22. The dummy electrode 6 is supplied with, for example, an emitter potential E, but the present invention is not limited to this, and the dummy electrode 6 may be supplied with another potential such as a gate potential.

The impurity concentration of each layer is as follows. For example, the impurity concentration of the drift layer 1 is a low concentration of n−, the impurity concentration of the emitter layer 7 is a high concentration of n+, and the impurity concentration of the cathode layer 12 is a high concentration of n+.

Here, in the semiconductor device 100 of Example 1, a gate resistance R of an IGBT in the vicinity of a boundary portion between the IGBT region 21 and the diode region 22 is greater than a gate resistance of an IGBT in the vicinity of a central portion of the IGBT region 21.

With such a simple structure, a timing at which the IGBT in the vicinity of the boundary portion is turned on is later than a timing at which the IGBT in the vicinity of the central portion is turned on, thereby making it possible to suppress a snapback phenomenon occurring when the IGBT is turned on, as will be described below, and a timing at which the IGBT in the vicinity of the boundary portion is turned off is later than a timing at which the IGBT in the vicinity of the central portion is turned off, making it possible to suppress hole implantation from the IGBT region into the diode region occurring when the diode is conductive, as will be described below.

FIG. 4 is a current-voltage characteristic illustrating the snapback phenomenon in an RC-IGBT.

In FIG. 4, the horizontal axis represents a voltage V and the vertical axis represents a current I. In FIG. 4, a characteristic 31 without snapback is shown by a dotted line, and a characteristic 32 with snapback is shown by a solid line.

In the IGBT, as shown in the characteristic 31 without snapback, normally the hole implantation starts when the voltage of a pn junction portion on the back surface side (the collector layer 11 of a p-type and the buffer layer 10 of an n-type in FIG. 1) becomes greater than or equal to a built-in voltage, and the IGBT starts an operation, and thus the current I rises in a curved line with respect to the voltage V.

However, in the RC-IGBT, when the IGBT is turned on, initially the voltage of the pn junction portion on the back surface side is lower than the built-in voltage, and therefore, in the vicinity of the boundary portion between the IGBT region 21 and the diode region 22, electrons 15 implanted from the body layer 2 on the front surface side of the IGBT do not escape from the p layer, which is the collector layer 11 on the back surface side of the IGBT, but escape to the n+ layer, which is the cathode layer 12 of the diode, and as shown by the characteristic 32 with snapback, initially a MOS operation in which the current I increases linearly with respect to the voltage V is performed. The reason is that the structure in which the n+ layer is used instead of the p layer on the back surface of the IGBT is the same as the structure of a metal oxide semiconductor field effect transistor (MOSFET). Thereafter, when the voltage applied to the pn junction portion on the back surface side rises and exceeds the built-in voltage, the IGBT starts an operation. At that time, the characteristic returns to the same as the characteristic 31 without snapback, and thus the voltage V temporarily decreases as shown by the characteristic 32 with snapback. This phenomenon is called the snapback phenomenon. When the snapback phenomenon occurs, the voltage during the MOS operation becomes higher than the waveform during the normal IGBT operation, resulting in a correspondingly larger loss.

In contrast, in the semiconductor device 100 of Example 1, due to a simple structure in which the gate resistance R of the IGBT in the vicinity of the boundary portion is made larger than that in the vicinity of the central portion, when the IGBT is turned on, the IGBT in the vicinity of the central portion, which is away from the vicinity of the boundary portion, is turned on before the IGBT in the vicinity of the boundary portion. As a result, as shown in FIG. 1, a path through which the electrons 15 from the IGBT in the vicinity of the central portion flow near the front surface of the pn junction portion on the back surface side to reach the cathode layer 12 of the diode becomes longer, and thus a voltage drop occurs while the electrons 15 flow over that length, resulting in a forward bias, and when the voltage exceeds the built-in voltage, the hole implantation from the collector layer 11 on the back surface side starts, and thus the snapback phenomenon occurring when the IGBT is turned on can be suppressed.

In addition, in the semiconductor device 100 of Example 1, due to a simple structure in which the gate resistance R of the IGBT in the vicinity of the boundary portion is made larger than that in the vicinity of the central portion, when the IGBT is turned off, the IGBT in the vicinity of the central portion, which is away from the vicinity of the boundary portion, is turned off before the IGBT in the vicinity of the boundary portion is turned off. The IGBT in the vicinity of the central portion which is turned off first is away from the vicinity of the boundary portion, and thus the amount of the hole implantation therefrom is small. In the IGBT in the vicinity of the boundary portion which is turned off later, a time for the hole implantation to occur is short, and thus the amount of the hole implantation therefrom can be reduced. As a result, the hole implantation from the IGBT region 21 into the diode region 22 occurring when the diode is conductive can be suppressed compared to the case in which the IGBTs are turned off at the same time.

Next, a method for making the gate resistance R of the IGBT in the vicinity of the boundary portion larger than that in the vicinity of the central portion in Example 1 will be described.

FIG. 2 is a plan view illustrating a shape of a gate wiring of the semiconductor device of Example 1.

As shown in FIG. 2, the gate wiring of the semiconductor device 100 of Example 1 includes a gate common wiring 16, which is also called a gate finger, and a gate lead-out wiring 17 connecting the gate common wiring 16 and each gate electrode 5, and a gate potential G is supplied to the gate electrode 5 via the gate wiring. In addition, the dummy electrodes 6 of the diode region 22 are connected to each other by a dummy wiring 18 and an emitter potential E is supplied thereto.

The gate lead-out wiring 17 of the IGBT in the vicinity of the boundary portion is thinner than the gate lead-out wiring 17 of the IGBT in the vicinity of the central portion. As a result, it is possible to make the gate resistance R of the IGBT in the vicinity of the boundary portion greater than that in the vicinity of the central portion.

Here, it is desirable that the gate lead-out wiring 17 becomes gradually thicker from the vicinity of the boundary portion toward the vicinity of the central portion. FIG. 2 shows an example in which the width of the gate lead-out wiring 17 becomes wider from the vicinity of the boundary portion toward the vicinity of the central portion, that is, Wc<Wb<Wa.

As a result, it is possible to obtain the effects of Example 1 more effectively.

In addition, since this can be achieved simply by changing the shape of the gate wiring, only the shape of a mask for patterning the gate wiring may be changed during manufacturing, and a new photolithography process or a new implantation process are not required, so there is no increase in manufacturing costs.

### Example 2

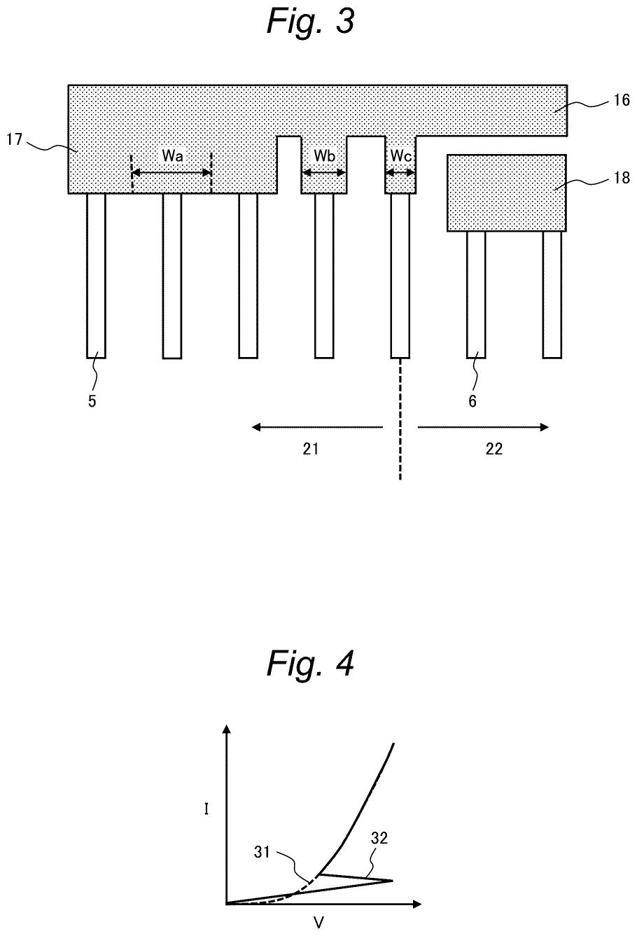

FIG. 3 is a plan view illustrating a shape of a gate wiring of a semiconductor device of Example 2.

Example 2 is a modification example of Example 1 and differs from Example 1 in that the gate lead-out wiring 17 is integrally formed by connecting the gate lead-out wirings 17, which are for the gate electrodes 5 adjacent to each other in the vicinity of the central portion, to each other. In this case, the width of the gate lead-out wiring 17 corresponding to each gate electrode 5 can be considered to be Wa shown in FIG. 3, because the midpoint between the adjacent gate electrodes 5 is considered to be a virtual boundary between the gate lead-out wirings 17. As a result, it is possible to reduce the gate resistance of the IGBT in the vicinity of the central portion as compared to Example 1. Other than this, this example is the same as Example 1, and thus the overlapping description will be omitted.

### Example 3

Example 3 is an example of a power conversion device in which the semiconductor device of Example 1 or Example 2 is used as a switching element. The configuration of the power conversion device is the same as a general configuration, and thus the detailed description thereof will be omitted.

Although the examples of the present invention have been described above, the present invention is not limited to the configurations described in the examples, and various modifications are possible within the scope of the technical concept of the present invention. In addition, some or all of the configurations described in each example may be combined and applied.

### REFERENCE SIGNS LIST

1 Drift layer
2 Body layer
3 Trench
4 Insulating film
5 Gate electrode
6 Dummy electrode
7 Emitter layer
8 Body contact layer
9 Interlayer insulating film
10 Buffer layer
11 Collector layer
12 Cathode layer
13 Front surface electrode
14 Back surface electrode
15 Electron
16 Gate common wiring
17 Gate lead-out wiring
18 Dummy wiring
21 IGBT region
22 Diode region
31 Characteristic without snapback
32 Characteristic with snapback
100 Semiconductor device
G Gate potential
E Emitter potential
A Anode potential
R Resistance
I Current
V Voltage

1. A semiconductor device comprising an IGBT region and a diode region in the same chip,
wherein a gate resistance of an IGBT in the vicinity of a boundary portion between the IGBT region and the diode region is greater than a gate resistance of an IGBT in the vicinity of a central portion of the IGBT region.

2. The semiconductor device according to claim 1, wherein a timing at which the IGBT in the vicinity of the boundary portion is turned on is later than a timing at which the IGBT in the vicinity of the central portion is turned on.

3. The semiconductor device according to claim 1, wherein a timing at which the IGBT in the vicinity of the boundary portion is turned off is later than a timing at which the IGBT in the vicinity of the central portion is turned off.

4. The semiconductor device according to claim 1, wherein a gate lead-out wiring of the IGBT in the vicinity of the boundary portion is thinner than a gate lead-out wiring of the IGBT in the vicinity of the central portion.

5. The semiconductor device according to claim 4, wherein the gate lead-out wiring becomes gradually thicker from the vicinity of the boundary portion toward the vicinity of the central portion.

6. The semiconductor device according to claim 1,
wherein the IGBT includes a drift layer of a first conductivity type, a trench, a gate electrode provided in the trench, a body layer of a second conductivity type provided adjacent to the trench on a front surface side relative to the drift layer, an emitter layer of a first conductivity type provided on a front surface side of the body layer, and a collector layer of a second conductivity type provided on a back surface side relative to the drift layer, and
wherein a diode in the diode region includes the drift layer, the body layer functioning as an anode layer of a second conductivity type provided on a front surface side relative to the drift layer, and a cathode layer of a first conductivity type provided on a back surface side relative to the drift layer.

7. A power conversion device comprising the semiconductor device according to claim 1 as a switching element.
